(19) United States
(12) Patent Application Publication
(10) Pub. No.: US 2011/0279949 A1
(43) Pub. Date: Nov. 17, 2011

(54) METHOD OF SECURING HINGE, AND ELECTRONIC APPARATUS

(75) Inventors: Yuji FUKAYA, Tokyo (JP); Hiroshi Yamamoto, Tokyo (JP); Yoshihisa Sakurai, Tokyo (JP); Katsumi Saito, Minato-ku (JP)

(73) Assignee: SONY ERICSSON MOBILE COMMUNICATIONS JAPAN, INC., Tokyo (JP)

(21) Appl. No.: 13/082,150

(22) Filed: Apr. 7, 2011

Related U.S. Application Data
(60) Provisional application No. 61/334,864, filed on May 14, 2010.

(51) Int. Cl. H05K 7/00; B23P 19/04

(52) U.S. Cl. 361/679.01; 29/428; 29/525.01

(57) ABSTRACT

An electronic apparatus including: a first case; a second case having an inclined arm fitting part; a hinge enabling the first and second cases to rotate around a first rotational axis; a secured piece secured to the hinge and the second case, the secured piece having an inclined arm part that fits into the inclined arm fitting part; and an inclined arm securing member configured to secure the inclined arm part fit to the inclined arm fitting part by insertion into a pair of gaps provided between the inclined arm fitting part and the inclined arm part.

### CROSS REFERENCE TO RELATED APPLICATIONS

This application is related to and claims priority under 35 U.S.C. §119(e) to Provisional Application Ser. No. 61/334,864, filed May 14, 2010, the contents of which are hereby incorporated herein by reference.

### BACKGROUND

1. Field

The present specification relates to a method of securing a hinge as well as an electronic apparatus suitable for joining two cases in such a manner that the cases pivot with respect to each other using a hinge, such as a one-axis hinge or a two-axis hinge.

More specifically, the present specification relates to an electronic apparatus and a method of securing a hinge in which two cases disposed in such a manner that they are aligned and parallel to each other (i.e., cases are disposed without being misaligned) are joined and in which misalignment of the cases is prevented even when the cases receive an impact after being joined.

As examples, embodiments may be applied to electronic apparatuses, such as personal handy-phone systems (PHSs), personal digital assistants (PDAs), portable game devices, digital cameras, moving-image acquisition devices, personal notebook computers, or containers in which the cover and the container part are joined using a hinge.

2. Description of the Related Art

Today, there are electronic apparatuses and containers in which a first pivoting part and a second pivoting part pivot with respect to each other by joining first ends of the first and second pivoting parts using a hinge.

For example, in case of a foldable mobile telephone having a one-axis hinge, a first case and a second case are joined with the one-axis hinge having one rotational axis along the shorter side of the cases. In this way, the foldable mobile telephone having the one-axis hinge opens by pivoting the cases with respect to each other around the rotational axis in the shorter side of the cases, allowing vertical opening.

Moreover, in case of a foldable mobile telephone having a two-axis hinge, a first case and a second case are joined with the two-axis hinge having a first rotational axis along the shorter side of the cases and a second rotational axis along the longer side of the cases. In this way, the foldable mobile telephone having the two-axis hinge vertically opens by pivoting the cases with respect to each other around the first rotational axis and horizontally opens by pivoting the cases with respect to each other around the second rotational axis.

In an assembling process of a mobile telephone in which a first case and a second case are joined using a hinge, assembly is carried out by adjusting the mounting position of the hinge such that the cases are aligned and parallel to each other when the cases are in a closed state.

However, in such an assembling process, even when the cases are assembled by adjusting the mounting position of the hinge such that the cases are aligned and parallel to each other, the mounting position of the hinge may be displaced by an increase in the number of components in the hinge, a variety in the size of the components, and an impact being applied from outside. In particular, for the two-axis hinge, since the number of components is larger than that of the one-axis hinge and the size of the components vary, the problem of displacement of the mounting position of the hinge is even more severe.

When the mounting position of the hinge is displaced, the cases aligned and parallel to each other in the above-described joining process result in being parallel to each other but misaligned. The magnitude of the misalignment of the cases due to the displacement of the mounting position of the hinge is greater at the edge opposite to the hinge, away from the hinge by a length equal to the longer side of the cases. In other words, even when the displacement is small at the mounting position of the hinge, the displacement becomes large at the edge of the cases opposite to the hinge.

To prevent such displacement of the mounting position of the hinge, for example, carefully selected components may be used. However, in such a case, there are problems in that the component cost increases, and the delivery period becomes long. Furthermore, to prevent such displacement of the mounting position of the hinge, for example, the mobile telephone may be constructed with looseness so that displacement in the mounting position of the hinge becomes less apparent, and the cases may be constructed in such a manner that misalignment of the cases is corrected by the cases themselves. However, in such a case, there are problems in that wobbling of the cases increases, and product quality decreases.

The inventors have investigated the related art and have discovered a technique disclosed in Japanese Unexamined Patent Application Publication No. 2009-108931.

Japanese Unexamined Patent Application Publication No. 2009-108931 discloses a mobile telephone in which cases are joined with a two-axis hinge having a first rotational axis along the shorter side of the cases and a second rotational axis along the longer side of the cases.

The two-axis hinge includes a first case-secured component, which is secured to the display-side case, and a first joining component, which is joined to the first case-secured component in such a manner that it pivots around the second rotational axis along the longer side of the cases.

Additionally, the two-axis hinge includes a second hinge component having a second joining component, which is joined with the operating-unit-side case in such a manner that it pivots around the first rotational axis along the shorter side of the cases.

The first joining component of the first hinge component and the second joining component of the second hinge component are engaged using two male threads provided at positions on the first rotational axis along the shorter side of the cases.

The first joining component has a correction protrusion protruding toward the second joining component, and the second joining component has a correction depression depressed in a direction opposite to the first joining component. Furthermore, the correction depression has an inclined surface, and when the first joining component and the second joining component are engaged using the male threads, the end of the correction protrusion contacts the inclined surface of the correction depression.

With such a hinge, when the display-side case is viewed with the edge on the side opposite to the hinge, the tightening of the male thread on the right side is increased when there is misalignment toward the left of display-side case. In contrast, when the display-side case is viewed with the edge on the side opposite to the hinge, the tightening of the male thread on the left side is increased when there is misalignment toward the right of display-side case. In other words, the male thread corresponding to the direction opposite to the direction of the misalignment in the display-side case is tightened more.

When the tightening of a male thread is increased, the correction protrusion is pulled toward the correction depression, and a force is applied in a direction causing misalignment of the correction protrusion and the correction depression. Accordingly, when the tightening of the male thread on the right side is increased, the display-side case pivots in the clockwise direction around the left-side male thread of which the tightening is not adjusted, and the misalignment toward the left of the display-side case is corrected. When the tightening of the male thread on the left side is increased, the display-side case pivots in the counterclockwise direction around the right-side male thread of which the tightening is not adjusted, and the misalignment toward the right of the display-side case is corrected.

With the mobile telephone disclosed in Japanese Unexamined Patent Application Publication No. 2009-108931, by adjusting the tightening of the male threads engaging the first joining component of the first hinge component and the second joining component of the second hinge component, misalignment in the cases can be corrected.

With the related art disclosed in Japanese Unexamined Patent Application Publication No. 2009-108931, by changing the level of tightening of the male threads, the level of contact of the correction protrusion of the first joining component and the correction depression of the second joining component is changed.

Therefore, the first joining component and the second joining component are engaged using the male threads with some space formed between the first joining component and the second joining component due to contact of the correction protrusion and the correction depression.

Accordingly, with the related art disclosed in Japanese Unexamined Patent Application Publication No. 2009-108931, when flat parts of the first joining component and second joining component are entirely in contract with each other, it becomes difficult to engaging the first joining component and the second joining component using the male threads. Consequently, there is a problem in that the rigidness and durability of the hinge decrease.

With the related art disclosed in Japanese Unexamined Patent Application Publication No. 2009-108931, the tightening of the male threads is adjusted individually for each mobile telephone. Therefore, there is a problem in mass production.

Furthermore, with the related art disclosed in Japanese Unexamined Patent Application Publication No. 2009-108931, when the size of the male threads is reduced to reduce the size of the hinge, the sensitivity for misalignment adjustment increases in such a manner that misalignment in the cases is over-adjusted in response to turning the male threads by a small amount. Accordingly, when the size of the male thread is reduced, there is a problem in that correction of misalignment in the cases becomes an extremely detailed process. To solve this problem, the size of the male threads may be increased, and the sensitivity for misalignment adjustment of the cases may be decreased. However, when the size of the male thread is increased, the overall size of the hinge increases, causing a problem in size-reduction of the electronic apparatus, e.g., mobile telephone, having a hinge.

### BRIEF SUMMARY

Embodiments of the present specification have been conceived in light of the above-described problems and provide an electronic apparatus and a method of securing a hinge that enable easy adjustment of displacement of cases without decreasing rigidness and durability even size reduction and that contribute to size reduction of electronic apparatuses and containers.

According to one embodiment, an electronic apparatus is provided comprising: a first case; a second case having an inclined arm fitting part; a hinge enabling the first and second cases to rotate around a first rotational axis; a secured piece secured to the hinge and the second case, the secured piece having an inclined arm part that fits into the inclined arm fitting part; and an inclined arm securing member configured to secure the inclined arm part fit to the inclined arm fitting part by insertion into a pair of gaps provided between the inclined arm fitting part and the inclined arm part.

According to another embodiment, a method is provided of securing a hinge of an electronic apparatus having a first case and a second case, the hinge including a secured piece secured to the second case, the second case having an inclined arm fitting part and the secured piece having an inclined arm part, the method comprising: securing the inclined arm part fit to the inclined arm fitting part by inserting an inclined arm securing member into a pair of gaps provided between the inclined arm fitting part and the inclined arm part.

Thus, to solve the above-described problems, in an embodiment of the present invention, a method of securing a hinge, having a first secured piece secured to a first case and a second secured piece secured to a second case, includes the steps of securing an inclined-arm part to the second secured piece of the hinge at a predetermined oblique angle with respect to a first rotational axis, which is substantially parallel to a predetermined side of the first and second cases, the cases being rotatable around the first rotational axis, from a closed state in which first surfaces of the cases face each other are aligned and parallel to each other to an open state in which the first surfaces of the cases form a predetermined opening angle, or the cases being rotatable around the first rotational axis, from the closed state in which the first surfaces of the cases face each other and are aligned and parallel to each other to a first open state in which the first surfaces of the cases form a first opening angle and being rotatable around a second rotational axis substantially orthogonal with the first rotational axis, from the closed state in which the first surfaces of the cases face each other and are aligned and parallel to each other to a second open state in which the first surfaces of the cases form a second opening angle; mounting an inclined-arm fitting part on the second case so as to form a pair of gaps between the inclined-arm part mounted on the second secured part and the second case in a direction orthogonal with the first rotational axis when the second secured piece of the hinge is mounted on the second case; and securing the hinge to the second case by fitting the inclined-arm part of the second secured part to the inclined-part fitting part of the second case, inserting an inclined-arm securing member into the pair of gaps formed between the inclined-arm fitting part and the inclined-arm part, and securing the inclined-arm part fit to the inclined-arm fitting part with the inclined-arm securing member.

In this way, the process of securing the hinge to the second case includes only two steps: a step of fitting the inclined-arm part of the second secured piece of the hinge to the inclined-arm fitting part of the second case after the first surfaces of the cases are aligned and parallel to each other; and a step of inserting the inclined-arm securing member into the pair of gaps formed between the inclined-arm fitting part and the inclined-arm part.

That is, since the inclined-arm part is fit to the inclined-arm fitting part of the second case when the first surfaces of the cases are aligned and parallel to each other, the fitting position of the inclined-arm is at a position where the first surfaces of the cases are aligned and parallel to each other.

In other words, by fitting the inclined-arm part to the inclined-arm fitting part of the second case while the first surfaces of the cases are aligned and parallel to each other, the fitting position where the inclined-arm part is fit to the inclined-arm fitting part is uniquely determined.

Therefore, by merely securing the inclined-arm part at the uniquely determined fitting position using the inclined-arm securing member, the hinge can join the cases such that the first surfaces of the cases are aligned and parallel to each other (i.e., the amount of misalignment of the cases can be easily adjusted).

Since the joining process merely includes the steps of fitting the inclined-arm part to the inclined-arm fitting part of the second case while the first surfaces of the cases are aligned and parallel to each other and securing the inclined-arm part at the fitting position of the inclined-arm part using the inclined-arm securing member, it is not necessary for assembly workers to have any special skills, and the joining process can be carried out easily even when the hinge is small.

Furthermore, since the inclined-arm part, which is fit together with the inclined-arm fitting part, is secured by inserting the inclined-arm securing member into the gaps, the inclined-arm part can be secured while filling the gaps. Thus, the inclined-arm part can be secured tightly, and rigidity can be increased. Moreover, since a high level of rigidity is achieved, even when the cases receive an impact from outside after assembly is completed, the cases can be reliably prevented from being misaligned, and high rigidity can be achieved.

According to an embodiment, the hinge can be secured while the first surfaces of the cases are aligned and parallel to each other through an easy joining process including merely the steps of fitting the inclined-arm part to the inclined-arm fitting part of the second case while the first surfaces of the cases are aligned and parallel to each other and securing the inclined-arm part at the fitting position of the inclined-arm part using the inclined-arm securing member.

Since such a joining process is easy, the joining process can be carried out by anyone, without special skills and detailed operations, even when the hinge is small.

Furthermore, since the inclined-arm part, which is fit to the inclined-arm fitting part, is secured by inserting the inclined-arm securing member into the gaps, the inclined-arm part can be secured while filling the gaps. Thus, the inclined-arm part can be secured tightly, and rigidity can be increased. Moreover, since a high level of rigidity is achieved, even when the cases receive an impact from outside after assembly is completed, the cases can be reliably prevented from being misaligned, and high rigidity can be achieved.

### BRIEF DESCRIPTION OF THE DRAWINGS

FIG. 1 is a perspective view of a mobile telephone according to a first embodiment, in a closed state;

FIG. 2 is an exploded perspective view of a first case and a second case of the mobile telephone according to the first embodiment;

FIG. 3 illustrates a second secured piece of a hinge to be mounted to the second case of the mobile telephone according to the first embodiment;

FIG. 4 is a front view of main parts of a two-axis hinge provided on the mobile telephone according to the first embodiment;

FIG. 5 is an enlarged front view of main parts of the two-axis hinge provided on the mobile telephone according to the first embodiment;

FIG. 6 illustrates the movement, along a second rotational axis, of the second secured piece of the hinge provided on the mobile telephone according to the first embodiment;

FIG. 7 also illustrates the movement, along the second rotational axis, of the second secured piece of the hinge provided on the mobile telephone according to the first embodiment;

FIG. 8 illustrates correction of misalignment of the cases by sandwiching with blocks the mobile telephone according to the first embodiment;

FIG. 9 is a perspective view of an inclined-arm securing member for securing a first arm part provided on the second secured piece of the hinge of the mobile telephone according to the first embodiment;

FIG. 10 illustrates positioning of the inclined-arm securing member fit together with an inclined-arm fitting part;

FIG. 11 illustrates protrusions of the inclined-arm securing member contacting substantially the center of a rail when the inclined-arm securing member is moved in the inclined-arm fitting part;

FIG. 12 illustrates the protrusions of the inclined-arm securing member contacting the rail near the right end of the inclined-arm fitting part when the upper gap becomes larger than the lower gap due to the first arm part moving away from the hinge (downward);

FIG. 13 illustrates the protrusions of the inclined-arm securing member contacting the rail near a screw when the lower gap becomes larger than the upper gap due to the first arm part moving close to the hinge (upward);

FIG. 14 illustrates the inclined-arm securing member fit together with the inclined-arm fitting part and secured with a screw;

FIG. 15 illustrates the movement of the second secured piece of the hinge along the second rotational axis (i.e., pivoting of the second secured piece around a pivoting point) being suppressed by the inclined-arm securing member fit together with the inclined-arm fitting part;

FIG. 16 is a perspective view of a mobile telephone according to a second embodiment, in a closed state;

FIG. 17 illustrates a second case of the mobile telephone according to the second embodiment, with the outer cover removed;

FIG. 18 is an enlarged view of a one-axis hinge provided on the mobile telephone according to the second embodiment; and

FIG. 19 is an enlarged view of main parts of a mobile telephone according to a third embodiment.

### DETAILED DESCRIPTION

An embodiment can be applied to a one-axis or a two-axis foldable mobile telephone.

### [Configuration of Mobile Telephone According to First Embodiment]

As a mobile telephone according to a first embodiment, a two-axis foldable mobile telephone will be described below.

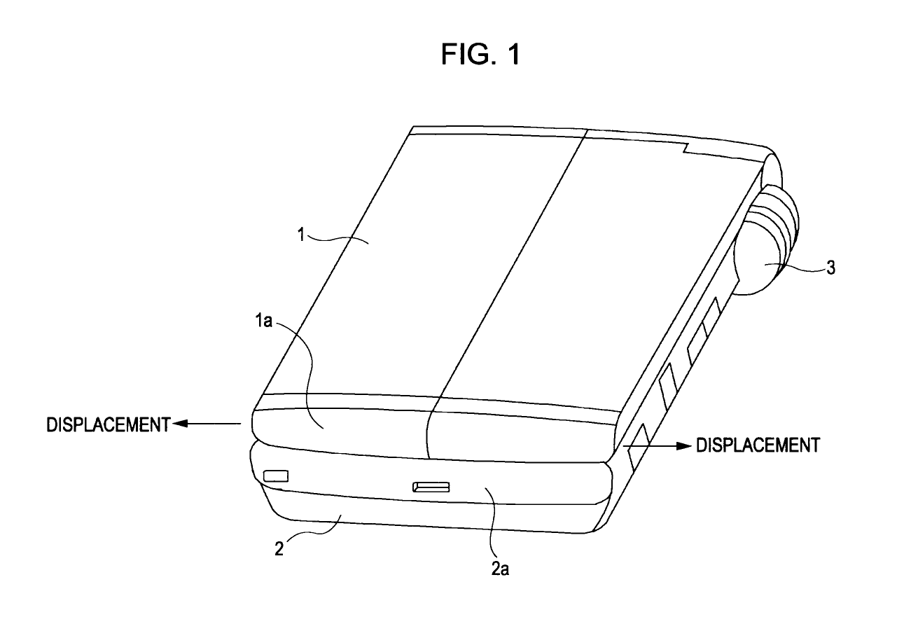

FIG. 1 is a perspective view of the two-axis mobile telephone according to the first embodiment, in a closed state. As illustrated in FIG. 1, the mobile telephone according to the first embodiment includes a substantially cuboidal first case 1 and a substantially cuboidal second case 2, which is substantially the same size as the first case 1. One of the sides of the cases 1 and 2 are joined using a hinge 3 in such a manner that they pivot with respect to each other.

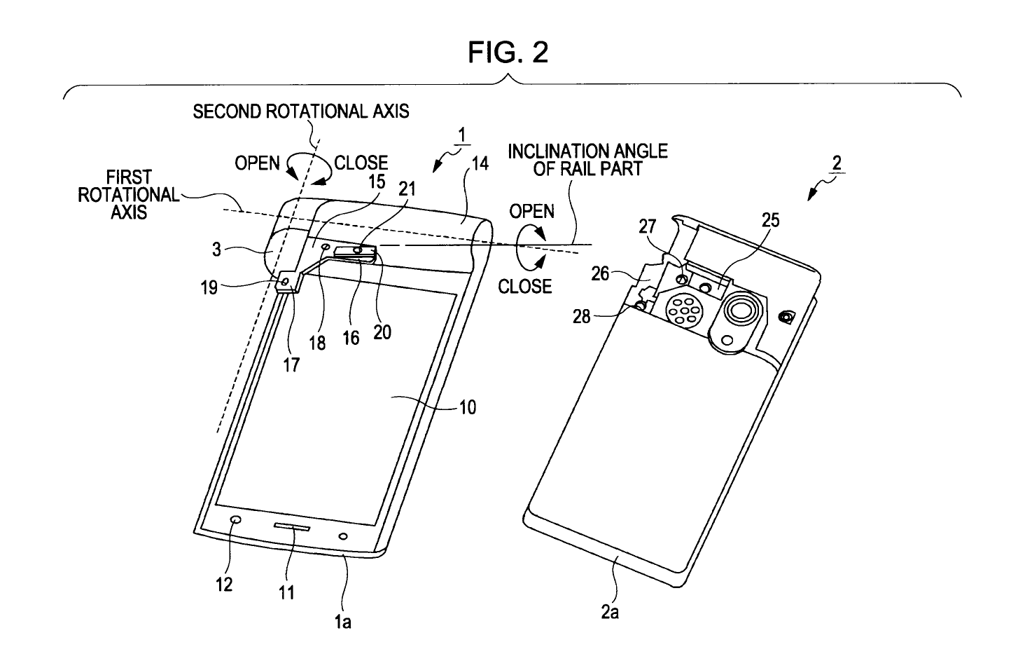

FIG. 2 is a perspective view of the mobile telephone with the first case 1 and the second case 2 disengaged. As illustrated in FIG. 2, the first case 1 includes, on the surface that contacts the second case 2 when the mobile telephone is closed, a display unit 10, a speaker unit 11 for audio communication, and a light-emitting window 12 through which light from a light-emitting unit, such as an LED, driven to emit light when sending and receiving telephone calls and text messages, is emitted.

The hinge 3 has a first secured piece, which is secured to the first case 1, and a second secured piece 15, which is secured to the second case 2. In FIG. 2, the first secured piece of the hinge 3 is secured to the first case 1 but is not visible since it is covered with a hinge cover 14. In other words, the first secured piece of the hinge 3 is secured to the first case 1 inside the hinge cover 14.

The hinge 3 has a first rotational axis, which is substantially parallel to the shorter sides of the cases 1 and 2, and a second rotational axis, which is substantially orthogonal with the first rotational axis.

The first rotational axis is used to vertically open the mobile telephone. The first rotational axis allows the cases 1 and 2 to pivot from a closed state (illustrated in FIG. 1) in which first surfaces of the cases 1 and 2 face each other and are aligned and parallel to each other to a vertical open state, in which the opening angle of the first surfaces of the cases 1 and 2 is a predetermined angle, e.g., approximately 170 degrees.

The second rotational axis is used to horizontally open the mobile telephone. The second rotational axis allows the cases 1 and 2 to pivot from a closed state (illustrated in FIG. 1) in which first surfaces of the cases 1 and 2 face each other and are aligned and parallel to each other to a vertical open state, in which the opening angle of the first surfaces of the cases 1 and 2 is a predetermined angle, e.g., approximately 130 degrees.

The second secured piece 15 of the hinge 3 has a first arm part 16, which extends along the shorter side of the first case 1, and a second arm part 17, which extends along the longer side of the first case 1, where the first arm part 16 and the second arm part 17 are joined in an inverted-L shape.

The first arm part 16 has a screw-hole part 18, which is used for securing the first arm part 16 to the second case 2. Similarly, the second arm part 17 has a screw-hole part 19, which is used for securing the second arm part 17 to the second case 2.

As illustrated in FIG. 2, a rail 20 protruding away from the display unit 10 (opposing an inclined arm-fitting part) is provided on the first arm part 16. As illustrated in FIG. 2, the rail 20 is disposed at a predetermined oblique angle with respect to the first rotational axis of the hinge 3. With the rail 20 disposed at an oblique angle, the first arm part 16 constitutes an inclined arm part.

A screw hole 21 is formed at substantially the center of the rail 20 and is used for securing an inclined arm securing member, which is described below, with a screw.

As illustrated in FIG. 2, the rail 20 is disposed on the first arm part 16 at an angle rising from left to right. Instead, however, the rail 20 may be disposed on the first arm part 16 at an angle rising from right to left. In either case, the advantages of this embodiment described below are achieved.

When the second case 2 is joined with the first case 1, the first arm part 16, which is the above-mentioned inclined arm, is fit into a first inclined-arm fitting part 25, and the second arm part 17 is fit into a second inclined-arm fitting part 26.

The inclined-arm fitting part 25 has a screw-hole part 27 through which a screw that is passed through the screw-hole part 18 formed in the first arm part 16 is passed. The second inclined-arm fitting part 26 has a screw-hole part 28 through which a screw that is passed through the screw-hole part 19 formed in the second arm part 17 is passed.

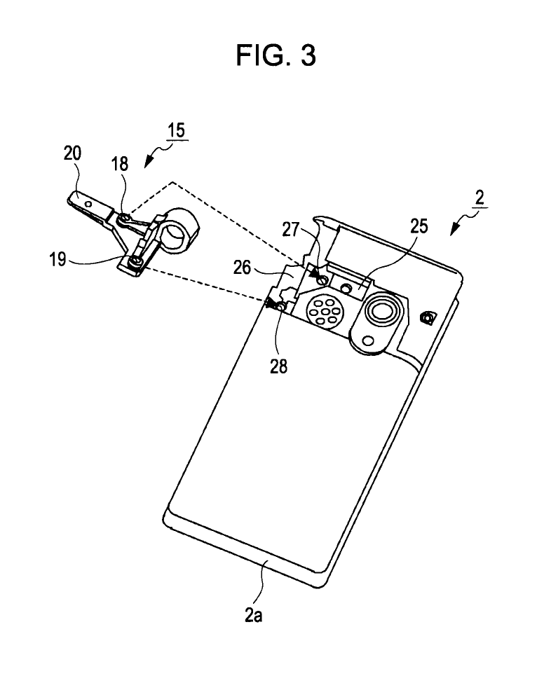

FIG. 3 is a perspective view of the second case 2 and the second secured piece 15 of the hinge 3. FIG. 3 illustrates a side of the second secured piece 15 not provided with the rail 20.

As illustrated in FIG. 3, the screw-hole part 18 formed in the first arm part 16 of the second secured piece 15 and the screw-hole part 19 formed in the second arm part 17 are substantially cylindrical protrusions protruding from the side not provided the rail 20.

In contrast, the screw-hole part 27 formed in the inclined-arm fitting part 25 of the second case 2 and the screw-hole part 28 formed in the second inclined-arm fitting part 26 of the second case 2 are depressions; the protruding screw-hole parts 18 and 19 of the arm parts 16 and 17 are fit into the screw-hole parts 27 and 28, respectively.

The diameter of the depressed screw-hole part 28 formed in the second inclined-arm fitting part 26 of the second case 2 is set such that the protruding screw-hole part 19 formed in the second arm part 17 fits into the screw-hole part 28 fairly tightly. As described below, the screw-hole parts 19 and 28 function as a rotational axis (pivoting point) around which the second secured piece 15 of the hinge 3 pivots.

The diameter of the depressed screw-hole part 27 formed in the inclined-arm fitting part 25 of the second case 2 is set such as to form a predetermined gap (which allows pivoting of the second secured piece 15 around the above-mentioned rotational axis (pivoting point)) between the protruding screw-hole part 18 and the depressed screw-hole part 27 when these screw-hole parts are fit together (i.e., the diameter of depressed screw-hole part 27 is larger than that of the protruding screw-hole part 18).

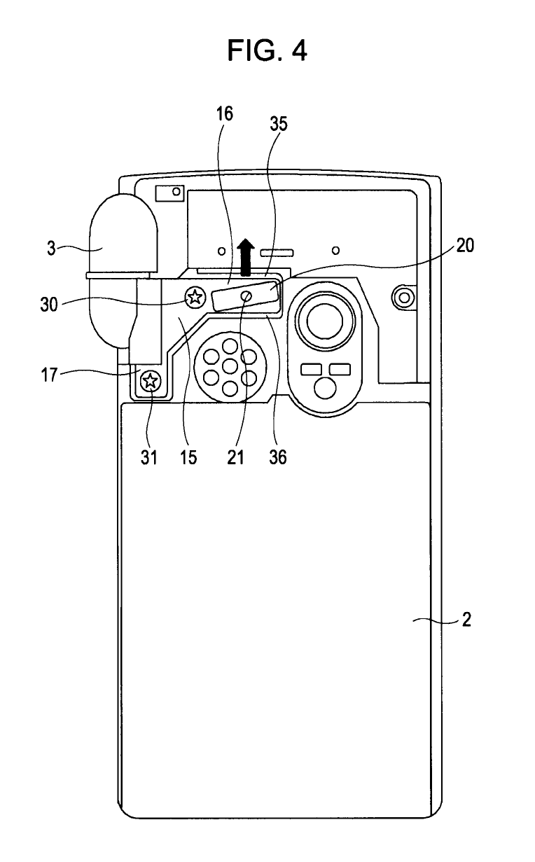

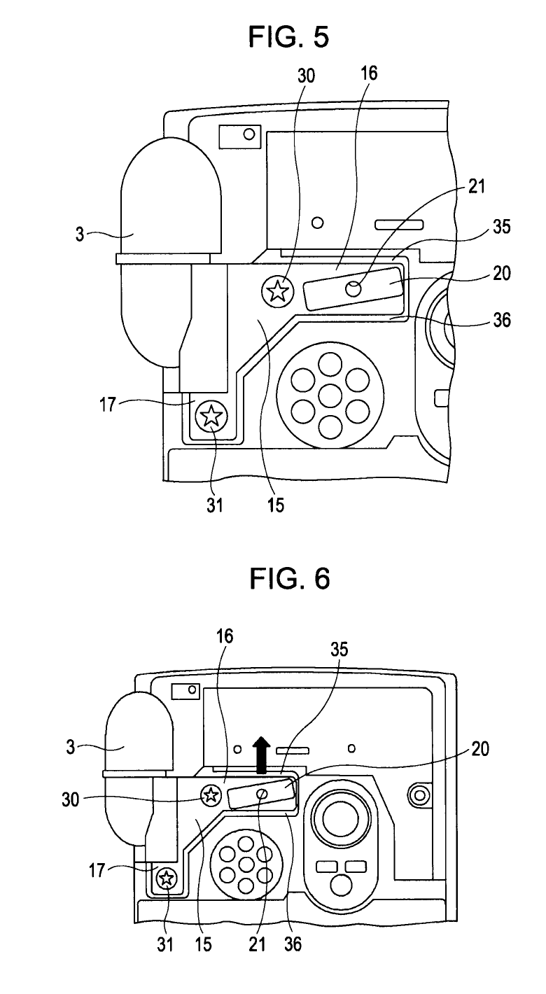

FIG. 4 illustrates the first case 1 and the second case 2 joined by the hinge 3 when viewed from the side provided with the second secured piece 15 of the hinge 3. FIG. 5 is an enlarged view of the second secured piece 15 of the hinge 3, which joins the first case 1 and the second case 2.

As illustrated in FIGS. 4 and 5, the first arm part 16 of the second secured piece 15 is fit into the inclined-arm fitting part 25 of the second case 2 and then secured to the second case 2 by a screw 30 passed through the screw-hole part 18 and the screw-hole part 27.

The second arm part 17 of the second secured piece 15 is fit into the second inclined-arm fitting part 26 of the second case 2 and then secured to the second case 2 by a screw 31 passed through the screw-hole part 19 and the screw-hole part 28.

When the first case 1 and the second case 2 are joined by the hinge 3 and the mobile telephone is closed, it is desirable that the cases 1 and 2 are parallel to each other without being misaligned, as illustrated in FIG. 1 (i.e., an end surface 1a of the cases 1 and an end surface 2a of the case 2 are aligned and parallel to each other).

However, in many cases, the first case 1 and/or the second case 2 are displaced in the directions indicated by arrows in FIG. 1 due to part accuracy of the parts in the hinge 3, assembly accuracy of the hinge 3 on the cases 1 and 2, and so on.

Therefore, when the second secured piece 15 of the hinge 3 is mounted on the second case 2 with screws, the mobile telephone is sandwiched by blocks 40 and 41 from directions parallel to the shorter side, as illustrated in FIG. 8, such that the cases 1 and 2 are aligned and parallel to each other (i.e., the displacement of the cases 1 and 2 is corrected). In this state, the position of the first arm part 16 in the inclined-arm fitting part 25 is determined as a position of the first arm part 16 at which the cases 1 and 2 are aligned and parallel to each other, and the screws 30 and 31 are tightened.

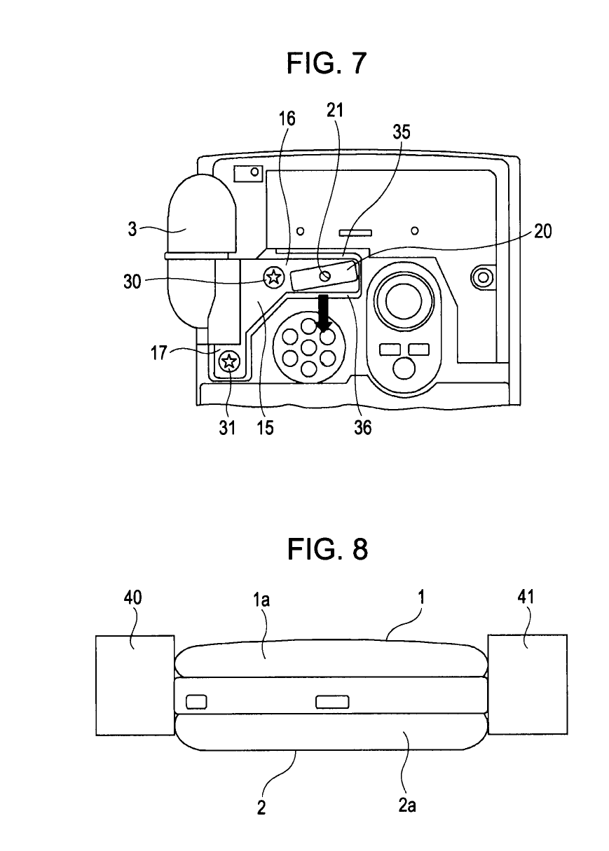

To correct the misalignment of the cases 1 and 2, the first arm part 16 should be movable in the inclined-arm fitting part 25 in directions indicated by the arrows in FIGS. 6 and 7.

Accordingly, a pair of gaps 35 and 36 orthogonal with the first rotational axis is provided, as illustrated in FIG. 5, between the second case 2 and the first arm part 16 fit into the inclined-arm fitting part 25. The depressed screw-hole part 28 in the second inclined-arm fitting part 26 of the second case 2 and the protruding screw-hole part 19 in the second arm part 17 are fit together with substantially no gap therebetween. In contrast, a predetermined gap is provided between the depressed screw-hole part 27 in the inclined-arm fitting part 25 of the second case 2 and the protruding screw-hole part 18 in the second arm part 17 by setting the diameter of the screw-hole part 27 larger than the diameter the screw-hole part 18.

That is, when the second secured piece 15 of the hinge 3 is mounted on the second case 2, the protruding screw-hole part 18 in the first arm part 16 of the second secured piece 15 is fit into the depressed screw-hole part 27 in the inclined-arm fitting part 25 of the second case 2, and the protruding screw-hole part 19 in the second arm part 17 is fit into the depressed screw-hole part 28 in the second inclined-arm fitting part 26 of the second case 2.

In this way, the second secured piece 15 of the hinge 3 is positioned and mounted to the second case 2 by fitting the protruding screw-hole parts 18 and 19 into the depressed screw-hole parts 27 and 28.

As described above, the gaps 35 and 36, which are orthogonal with the first rotational axis, are provided between the second case 2 and the first arm part 16, which is fit into to the inclined-arm fitting part 25. The depressed screw-hole part 28 in the second inclined-arm fitting part 26 of the second case 2 and the protruding screw-hole part 19 in the second arm part 17 are fit together with substantially no gap therebetween. In contrast, a predetermined gap is provided between the depressed screw-hole part 27 in the inclined-arm fitting part 25 of the second case 2 and the protruding screw-hole part 18 in the second arm part 17 by setting the diameter of the screw-hole part 27 larger than the diameter the screw-hole part 18.

For this reason, even after being positioned, the second secured piece 15 can pivot with respect to the longer side of the mobile telephone around a “pivoting point” at a screw hole formed by fitting the protruding screw-hole part 19 in the second arm part 17 of the second secured piece 15 into the depressed screw-hole part 28 in the second inclined-arm fitting part 26 of the second case 2 (i.e., the second secured piece 15 can pivot around a rotational axis at the pivoting point by means of the gaps 35 and 36 and the gap formed between the screw-hole part 18 and the screw-hole part 27).

In the mobile telephone according to this embodiment, misalignment of the cases 1 and 2 is corrected by pivoting the second secured piece 15 with respect to the longer side of the mobile telephone around the rotational axis at the pivoting point after positioning. Then, after such correction, the second secured piece 15 of the hinge 3 is screwed to the second case 2.

When the second secured piece 15 of the hinge 3 is merely mounted to the second case 2 using the screws 30 and 31, the contact strength of the second secured piece 15 and the second case 2, which are in surface-contact with each other, is increased merely by the screws 30 and 31. Therefore, in this state, if the cases 1 and 2 receive an impact from outside, the cases 1 and 2 may pivot around the rotational axis at the pivoting point (at the screw-hole parts 19 and 28 and the screw 31), as indicated by the arrows in FIGS. 6 and 7, causing the cases 1 and 2 to be misaligned again.

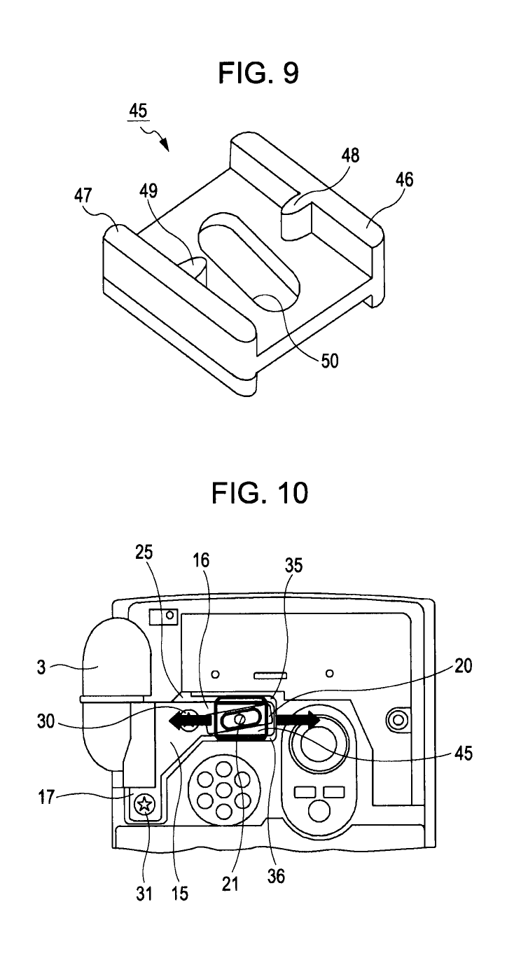

Thus, with the mobile telephone according to this embodiment, by mounting an inclined-arm securing member 45, which is illustrated in FIG. 9, to the inclined-arm fitting part 25, the position of the first arm part 16 (inclined-arm part) is secured in the inclined-arm fitting part 25.

FIG. 9 is a perspective view of the inclined-arm securing member 45 illustrating the side to be mounted to the inclined-arm fitting part 25 (i.e., the side opposing the inclined-arm fitting part 25). The inclined-arm securing member 45 is made of, for example, elastomer, metal, or ABS resin, and, as illustrated in FIG. 9, its width is slightly smaller than the width of the inclined-arm fitting part 25 in the direction orthogonal to the first rotational axis (i.e., a width that allows the inclined-arm securing member 45 to be fit into the inclined-arm fitting part 25 without forming a gap).

The inclined-arm securing member 45 has a pair of gap insertion parts 46 and 47, which are provided in the direction of the first rotational axis and are respectively inserted into the gaps 35 and 36 formed between the first arm part 16 and the second case 2.

Moreover, the inclined-arm securing member 45 has a pair of protrusions 48 and 49, which are provided on the gap insertion parts 46 and 47, respectively, and protrude toward the rail 20 of the first arm part 16.

Furthermore, the inclined-arm securing member 45 has a long hole 50 formed at substantially the same angle as the angle of the rail 20 of the first arm part 16. A screw, which serves as a securing pin, is passed through the long hole 50. By passing the screw through the long hole 50 and engaging it with the screw hole 21, the inclined-arm securing member 45 is mounted and secured to the first arm part 16.

### [Process of Joining Cases Using Hinge]

Next, a process of joining the cases 1 and 2 using the hinge 3 in the mobile telephone according to this embodiment having the above described configuration will be described.

In the mobile telephone according to the embodiment, to join the cases 1 and 2 using the hinge 3, first, the first secured piece of the hinge 3 is secured to the first case 1 with a screw.

Then, as illustrated in FIG. 3, the first case 1 and the second case 2 are temporarily assembled by fitting the protruding screw-hole part 18 in the first arm part 16 of the second secured piece 15 of the hinge 3 into the depressed screw-hole part 27 in the inclined-arm fitting part 25 of the second case 2 and by fitting the protruding screw-hole part 19 in the second arm part 17 into the depressed screw-hole part 28 formed in the second inclined-arm fitting part 26 of the second case 2.

Then, as illustrated in FIG. 8, the mobile telephone is sandwiched by the blocks 40 and 41 from directions parallel to the shorter side. In this way, the second case 2 pivots via the second secured piece 15 around the rotational axis at the pivoting point (at the screw-hole parts 19 and 28 and the screw 31) with respect to the longer side of the mobile telephone, and the cases 1 and 2 disposed in such a manner that they are aligned and parallel to each other (i.e., misalignment in the cases 1 and 2 is corrected). Then, in this state, the position of the first arm part 16 in the inclined-arm fitting part 25 is determined as the position of the first arm part 16 at which the cases 1 and 2 are aligned and parallel to each other, and the second secured piece 15 of the hinge 3 is screwed to the second case 2.

Subsequently, by inserting the gap insertion parts 46 and 47 of the inclined-arm securing member 45 into the respective gaps 35 and 36 between the first arm part 16 and the second case 2 and by moving the inclined-arm securing member 45 with the assembler's finger in a direction along the first rotational axis, as indicated by the arrows in FIG. 10, the protrusion 48 and/or the protrusion 49 of the inclined-arm securing member 45 contact the rail 20 of the first arm part 16. Then, at the position where the protrusions 48 and 49 contact the rail 20, the inclined-arm securing member 45, which is illustrated in FIG. 10, is fit into the inclined-arm fitting part 25 of the second case 2. By fitting the inclined-arm securing member 45 in such way, it is secured to the inclined-arm fitting part 25, and the position of the first arm part 16 is fixed in the inclined-arm fitting part 25 by the inclined-arm securing member 45.

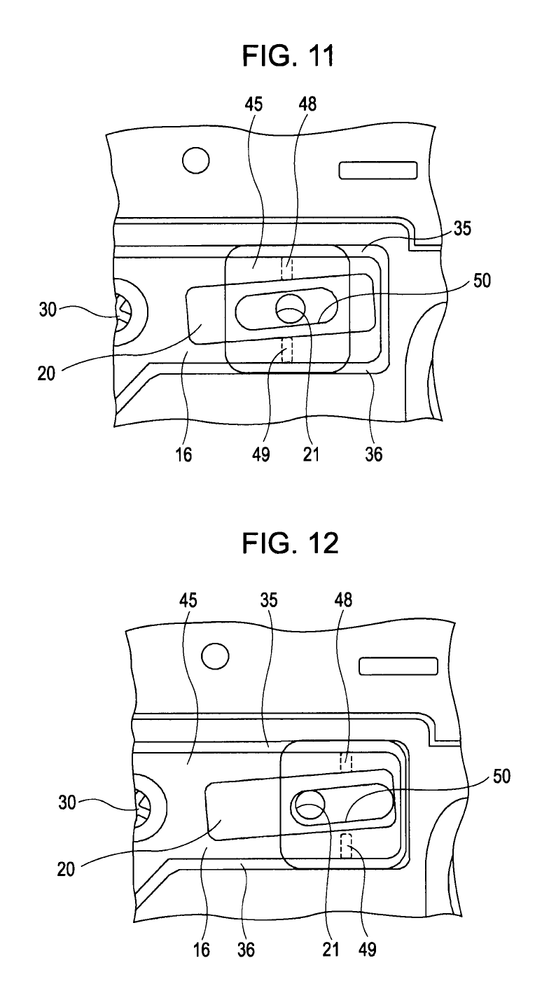

FIG. 11 illustrates the protrusions 48 and 49 of the inclined-arm securing member 45 contacting substantially the center of the rail 20 when the inclined-arm securing member 45 is moved in the inclined-arm fitting part 25.

FIG. 12 illustrates a state in which the protrusion 48 and/or the protrusion 49 of the inclined-arm securing member 45 contact the rail 20 near the right end of the inclined-arm fitting part 25 when the gap 35 becomes larger than the gap 36 (i.e., gap 35>gap 36) due to the first arm part 16 being positioned away from the hinge 3 (downward).

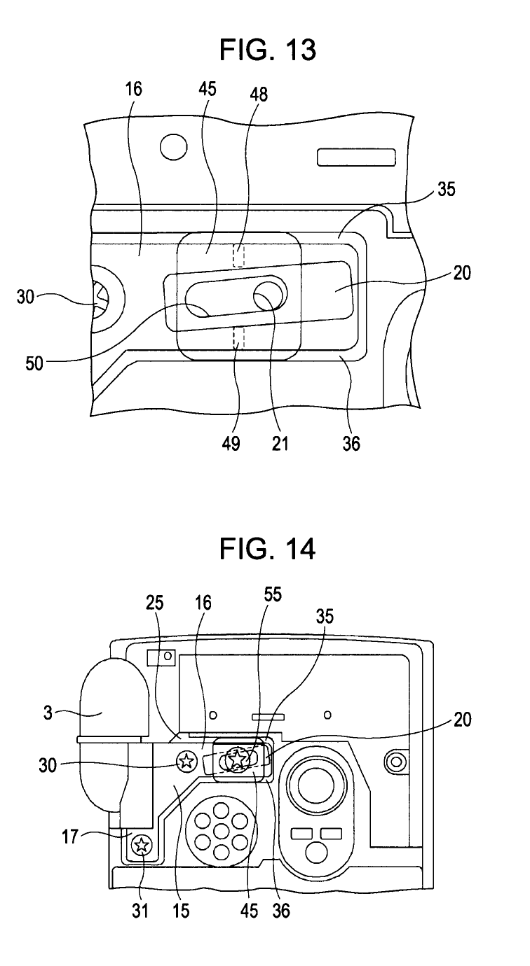

FIG. 13 illustrates a state in which the protrusion 48 and/or the protrusion 49 of the inclined-arm securing member 45 contact the rail 20 near the screw 30 when the gap 36 becomes larger than the gap 35 (i.e., gap 35<gap 36) due to the first arm part 16 being positioned toward the hinge 3 (upward).

Then, with the protrusion 48 and/or the protrusion 49 of the inclined-arm securing member 45 contacting the rail 20, a screw 55, which is illustrated in FIG. 14, is engaged with the screw hole 21 of the rail 20 through the long hole 50 of the inclined-arm securing member 45.

In this way, the inclined-arm securing member 45 is tightly secured to the first arm part 16 of the hinge 3, and the second secured piece 15 of the hinge 3 is secured to the second case 2 by the screws 30 and 31 and the inclined-arm securing member 45. Accordingly, the process of joining the cases 1 and 2 using the hinge 3 ends.

### [Function of Hinge]

As illustrated in FIG. 9, the inclined-arm securing member 45 has a width that is slightly smaller than the width of the inclined-arm fitting part 25 in the direction orthogonal to the first rotational axis (i.e., a width that allows the inclined-arm securing member 45 to be fit into the inclined-arm fitting part 25 without forming a gap).

By sandwiching the mobile telephone by the blocks 40 and 41 from directions parallel to the shorter side, as illustrated in FIG. 8, when joining the cases 1 and 2 using the hinge 3, the gaps 35 and 36 formed between the first arm part 16 and the second case 2 and the gap formed between the depressed screw-hole part 27 and the protruding screw-hole part 18 allow the second case 2 to pivot via the second secured piece 15 around the rotational axis at the pivoting point (at the screw-hole parts 19 and 28 and the screw 31) with respect to the longer side of the mobile telephone, and misalignment of the cases 1 and 2 can be corrected. Then, in this state, the position of the first arm part 16 in the inclined-arm fitting part 25 is uniquely determined as a position of the first arm part 16 at which the cases 1 and 2 are disposed in such a manner that they are aligned and parallel to each other.

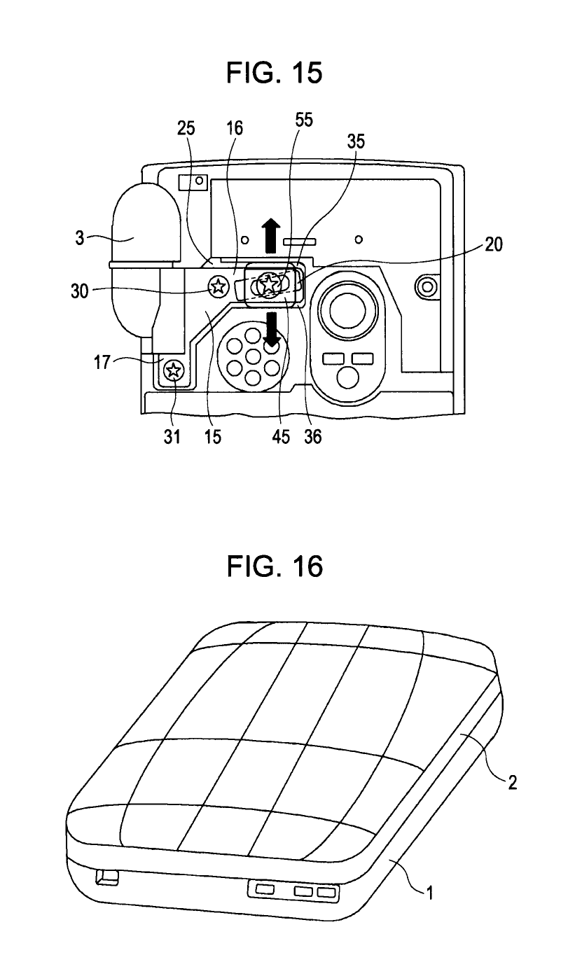

Therefore, by fitting together the inclined-arm securing member 45 with the rail 20 of the first arm part 16 with the protrusion 48 and/or the protrusion 49 of the inclined-arm securing member 45 contacting the rail 20, the movement of the first arm part 16 in the directions indicated by the arrows in FIG. 15, which are directions orthogonal with the rotational axis, is strongly prevented by the inclined-arm securing member 45, and the corrected alignment of the cases 1 and 2 can be maintained reliably.

In other words, the inclined-arm securing member 45 fills the gaps 35 and 36 between the first arm part 16 and the second case 2 to strongly prevent the movement of the first arm part 16 in the directions indicated by the arrows in FIG. 15, which are directions orthogonal with the rotational axis, and the corrected alignment of the cases 1 and 2 can be maintained reliably.

Since the inclined-arm securing member 45 can strongly prevent the movement of the first arm part 16 in the directions indicated by the arrows in FIG. 15, which are directions orthogonal with the rotational axis, even when the cases 1 and 2 receive an impact from outside after correcting the alignment of the cases 1 and 2, the movement of the first arm part 16 can be strongly prevented. Therefore, even after the alignment of the cases 1 and 2 is corrected, the alignment of the first case 1 and/or the second case 2 can be further corrected when they are further misaligned.

### [Advantage of First Embodiment]

As described above, in the mobile telephone according to this embodiment, the cases 1 and 2 can be joined with the hinge 3 through the following four steps.

1. A first step of securing the first secured piece of the hinge 3 to the first case 1 with a screw.
2. A second step of positioning the second secured piece 15 by fitting the protruding screw-hole part 18 in the first arm part 16 of the second secured piece 15 of the hinge 3 into the depressed screw-hole part 27 in the inclined-arm fitting part 25 of the second case 2 and fitting the protruding screw-hole part 19 in the second arm part 17 into the depressed screw-hole part 28 of the second inclined-arm fitting part 26 of the second case 2.
3. A third step of correcting the alignment of the cases 1 and 2 and securing the second secured piece 15 of the hinge 3 to the second case 2 using the screw 30 and the screw 31 by pivoting the positioned second secured piece 15 around the rotational axis at the pivoting point (at the screw-hole parts 19 and 28 and the screw 31) with respect to the longer side of the mobile telephone and by pivoting the second case 2 by the second secured piece 15 of the second case 2.
4. A fourth step of fitting the inclined-arm securing member 45 together with the inclined-arm fitting part 25 of the second case 2 at a position where the protrusion 48 and/or the protrusion 49 of the inclined-arm securing member 45 contact the rail 20 of the first arm part 16 and securing the first arm part 16 with the inclined-arm securing member 45.

When the process is broken down into four steps, this might seem like many steps. Actually, however, the cases 1 and 2 can be joined using the hinge 3 in an extremely simple process of performing positioning by fitting the second secured piece 15 of the hinge 3, which is fit together with the first secured piece, together with the first case 1, fitting the inclined-arm securing member 45 together with the inclined-arm fitting part 25, and securing the first arm part 16 using the inclined-arm securing member 45.

The step of securing the first arm part 16 using the inclined-arm securing member 45 is a step of merely finding the position where the protrusion 48 and/or the protrusion 49 contact the rail 20 and fitting the inclined-arm securing member 45 together with the inclined-arm fitting part 25 of the second case 2.

That is, after positioning, the alignment of the cases 1 and 2 is corrected after the first arm part 16 is set at the position reached by pivoting around the rotational axis at the pivoting point (at the screw-hole parts 19 and 28 and the screw 31); consequently, the position where the inclined-arm securing member 45 is fit together with the inclined-arm fitting part 25 is determined uniquely.

Therefore, the process to be carried out does not included detailed steps and merely includes a step of securing the first arm part 16 by fitting the inclined-arm securing member 45 together with the inclined-arm fitting part 25 after correcting the alignment of the cases 1 and 2. Thus, the process can be carried out easily and quickly by anyone.

Since the process is easy, even when the size of the hinge 3 is reduced, anyone can carry out the process easily and quickly in the same manner. Accordingly, by reducing the size of the hinge 3, the size of the mobile telephone can be reduced.

Since the inclined-arm securing member 45 fills the gaps 35 and 36 between the first arm part 16 and the second case 2, the movement of the first arm part 16 in the directions indicated by the arrows in FIG. 15, which are directions orthogonal with the rotational axis, can be strongly prevented, and the corrected alignment of the cases 1 and 2 can be maintained reliably.

Since the inclined-arm securing member 45 can strongly prevent the movement of the first arm part 16 in the directions indicated by the arrows in FIG. 15, which are directions orthogonal with the rotational axis, even when the cases 1 and 2 receive an impact from outside after correcting the alignment of the cases 1 and 2, the movement of the first arm part 16 can be strongly prevented. Accordingly, even after the alignment of the cases 1 and 2 is corrected, the alignment of the first case 1 and the second case 2 can be further corrected when they are further misaligned.

### [Variation of First Embodiment]

As described above in the first embodiment, the inclined-arm securing member 45 is secured to the rail 20 of the first arm part 16 with the screw 55. Instead, however, the inclined-arm securing member 45 may simply be fit together with the inclined-arm fitting part 25. In such a case, pressure may be applied to the inclined-arm securing member 45 fit together with the inclined-arm fitting part 25 by a hinge covered or the like to firmly maintain the fitting position of the inclined-arm securing member 45.

In this way, the long hole 50 of the inclined-arm securing member 45, the screw hole 21 in the rail 20, and the screw 55 may be omitted to simplify the configuration.

Since the inclined-arm securing member 45 is simply fit together with the inclined-arm fitting part 25 so that the position of the first arm part 16 is secured where the cases 1 and 2 are parallel to each other without being misaligned, the above-described joining process can be simplified even more. Instead of the screw 55, a securing pin may be used to secure the inclined-arm securing member 45 to the rail 20 of the first arm part 16 by inserting the securing pin into a hole in the rail 20 (i.e., the inclined-arm securing member 45 may be secured with a rod-like, e.g., cylindrical, securing pin instead of the screw 55).

### Second Embodiment

A mobile telephone according to a second embodiment will be described below. The mobile telephone according to the above-described first embodiment has the two-axis hinge 3. In contrast, the mobile telephone according to the second embodiment has a one-axis hinge that only allows the mobile telephone to be opened vertically.

### [Configuration of Mobile Telephone According to Second Embodiment]

FIG. 16 is a perspective view of the mobile telephone according to the second embodiment in a closed state. As illustrated in FIG. 16, the mobile telephone according to the second embodiment includes substantially cuboidal first case 1 and second case 2. On the surface of the first case 1 opposing the second case 2 when the mobile telephone is closed, operating units, such as ten-keys and a cross key, a microphone unit for communication, and so on are provided. On the surface of the second case 2 opposing the first case 1 when the mobile telephone is closed, a display unit, a speaker unit for communication, and so on are provided.

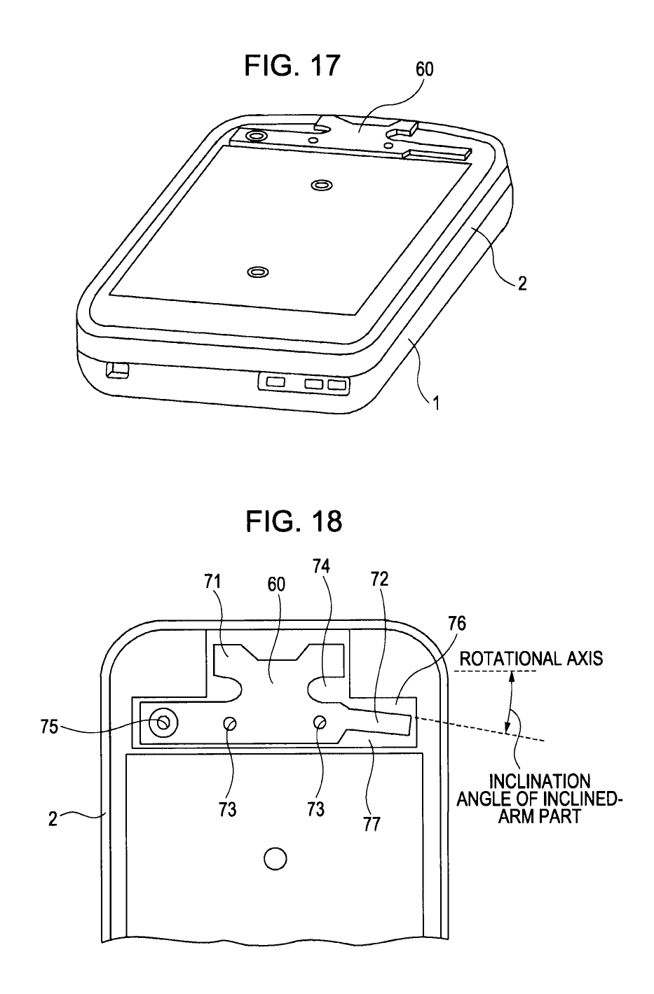

FIG. 17 illustrates the mobile telephone illustrated in FIG. 16 with an outer cover removed from the second case 2. As illustrated in FIG. 17, the cases 1 and 2 are joined by a one-axis hinge 60, which joins first sides of the cases 1 and 2. The hinge 60 has a rotational axis along the shorter side of the cases 1 and 2.

The hinge 60 joins the cases 1 and 2 in such a manner that the cases 1 and 2 pivot relative to each other from a closed state (illustrated in FIGS. 16 and 17) in which the cases 1 and 2 are substantially aligned and parallel to each other to an open state in which the opening angle of the surfaces of the cases 1 and 2 opposing each other in the closed state is approximately 170 degrees.

FIG. 18 illustrates an enlarged view of the hinge 60.

The hinge 60 has a first secured piece joined with the first case 1 and a second secured piece 71 joined with the second case 2. As illustrated in FIG. 18, the second secured piece 71 is shaped as the letter H turned by 90 degrees when viewed from the front.

The area near one of the edges of the second secured piece 71 constitutes an inclined arm part 72 that is disposed at a predetermined angle to the rotational axis along the shorter side of the cases 1 and 2.

As illustrated in FIG. 18, the inclined arm part 72 of the second secured piece 71 has a slope rising from right to left. Instead, however, the slope may rise from left to right. In either case, the same advantages described below are achieved.

At substantially the center of the second secured piece 71, a pair of screw holes 73 used for securing the second secured piece 71 to the second case 2 with screws is formed.

Near the other edge of the second secured piece 71 (near an edge opposite to the inclined arm part 72), a cylindrically protruding screw-hole part 75 (having a shape similar to that of the screw-hole parts 18 and 19 illustrated in FIG. 3) is formed in such a manner that it protrudes toward the second case 2 when the second arm part 17 is fit together with the second case 2.

The second secured piece 71 is fit together with an inclined-arm fitting part 74 of the second case 2. In the inclined-arm fitting part 74, a depressed screw-hole part (having a shape similar to that of the screw-hole parts 27 and 28 illustrated in FIG. 3) into which the screw-hole part 75 is fit is formed at a position corresponding to the protruding screw-hole part 75 in the second secured piece 71 fit into the inclined-arm fitting part 74.

The inclined-arm fitting part 74 has a pair of gaps 76 and 77 formed in a direction orthogonal with the rotational axis between the second case 2 and the inclined arm part 72 of the second secured piece 71.

For the mobile telephone according to this embodiment, the protruding screw-hole part 75 in the second secured piece 71 is fit into the depressed screw hole in the inclined-arm fitting part 74 with substantially no gap formed therebetween. The screw hole formed by fitting the protruding screw-hole part 75 in the second secured piece 71 into the depressed screw hole in the inclined-arm fitting part 74 with substantially no gap formed therebetween serves as the above-described “pivoting point.”

With the mobile telephone according to the second embodiment, the alignment of the cases 1 and 2 is corrected by pivoting the second secured piece 71, which is fit into the inclined-arm fitting part 74, around the rotational axis at the pivoting point, and the second secured piece 71 is secured to the second case 2 using the inclined-arm securing member 45 by inserting the gap insertion parts 46 and 47 of the inclined-arm securing member 45, which are illustrated in FIG. 9, into the gaps 76 and 77.

[Process of Joining Cases with Hinge]

Next, the process of joining the cases 1 and 2 with the hinge 60 in the mobile telephone according to the second embodiment having the above described configuration will be described.

In the mobile telephone according to the second embodiment, to join the cases 1 and 2 using the hinge 60, the first secured piece of the hinge 60 is secured to the first case 1 with a screw.

Next, as illustrated in FIG. 18, the first case 1 and the second case 2 are temporarily assembled by engaging the protruding screw-hole part 75 in the second secured piece 71 of the hinge 60 with the depressed screw hole in the inclined-arm fitting part 74 of the second case 2.

Then, as illustrated in FIG. 8, the mobile telephone is sandwiched by the blocks 40 and 41 from directions parallel to the shorter side. In this way, the second case 2 pivots via the second secured piece 71 around the rotational axis at the pivoting point (the screw-hole part 75 and the screw hole in the inclined-arm fitting part 74) with respect with the longer side of the mobile telephone, and the cases 1 and 2 are disposed in such a manner that they are aligned and parallel to each other (i.e., the alignment of the cases 1 and 2 is corrected).

In this state, the position of the inclined arm part 72 in the inclined-arm fitting part 74 is determined as a position of the inclined arm part 72 at which the cases 1 and 2 are aligned and parallel to each other, and the second secured piece 71 of the hinge 60 is mounted to the second case 2 with the screws passed through the screw hole serving as the pivoting point and the screw hole 73.

Next, the gap insertion parts 46 and 47 of the inclined-arm securing member 45, which are illustrated in FIG. 9, are lightly inserted into the gaps 76 and 77, respectively, formed between the inclined arm part 72 and the second case 2. Then, by moving the inclined-arm securing member 45 along the rotational axis by the assembler's finger, the position where the protrusion 48 and/or the protrusion 49 of the inclined-arm securing member 45 contact the inclined arm part 72 is determined.

Finally, at the position where the protrusion 48 and/or the protrusion 49 of the inclined-arm securing member 45 contact the inclined arm part 72, the inclined-arm securing member 45 is fit into the inclined-arm fitting part 74 of the second case 2.

In this way, the inclined arm part 72 is secured by the inclined-arm securing member 45; the second secured piece 71 of the hinge 60 is secured to the second case 2 by the secured inclined arm part 72; and the process of joining the cases 1 and 2 using the hinge 60 ends.

The alignment of the cases 1 and 2 is corrected after the inclined-arm part 72 is set at the position reached by pivoting the second secured piece 71 around the rotational axis at the pivoting point; consequently, the position where the inclined-arm securing member 45 is fit together with the inclined-arm fitting part 74 is determined uniquely.

Therefore, the process to be carried out does not included detailed steps and merely includes a step of securing the inclined arm part 72 by fitting the inclined-arm securing member 45 together with the inclined-arm fitting part 74 after correcting the alignment of the cases 1 and 2. Thus, the process can be carried out easily and quickly by anyone.

In this case, the inclined arm part 72 is secured to the second case 2 by merely fitting the inclined-arm securing member 45 together with the inclined-arm fitting part 74. Instead, however, as described in the first embodiment, the inclined-arm securing member 45 may be secured with a screw. In such a case, the inclined arm part 72 can be secured to the second case 2 more firmly.

### [Advantage of Second Embodiment]

As described above, even when the one-axis hinge 60 is used, the cases 1 and 2 can be joined using the hinge 60 through a simple process of merely securing the inclined arm part 72 of the second secured piece 71 using the inclined-arm securing member 45. Therefore, the same advantages as those of the mobile telephone according to the first embodiment can be achieved.

### Third Embodiment

Next, a mobile telephone according to a third embodiment will be described. In the mobile telephones according to the above-described embodiments, the first arm part 16 or the inclined arm part 72 is secured using the inclined-arm securing member 45. In contrast, in the mobile telephone according to the third embodiment, a bonding member is used as an inclined-arm securing member, and by injecting the bonding member into the gaps 35 and 36 formed between the first arm part 16 and the second case 2 or the gaps 76 and 77 formed between the inclined arm part 72 and the second case 2, the first arm part 16 or the inclined arm part 72 is secured.

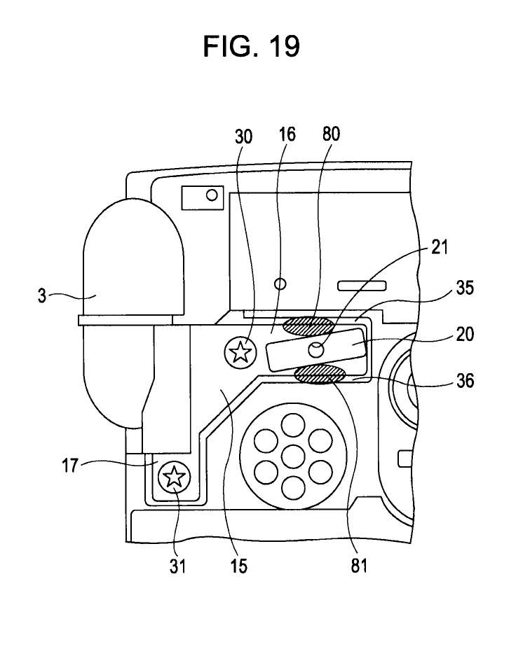

FIG. 19 illustrates bonding members 80 and 81, which are inclined-arm securing members, used on the two-axis hinge 3 described in the first embodiment. Since the same configuration is employed for the one-axis hinge 60, the operation and advantages of using the bonding members as inclined-arm securing members on the one-axis hinge 60 are the same as those described below.

In the mobile telephone according to the third embodiment, as illustrated in FIG. 19, the bonding members 80 and 81, such as ultraviolet curable resin which cures when irradiated with ultraviolet rays or resin that cures and dries over time, are injected into the gaps 35 and 36 formed between the first arm part 16 and the second case 2.

In this way, the gaps 35 and 36 can be filled with the bonding members 80 and 81, and the first arm part 16 can be secured to the second case 2.

With the mobile telephone according to the third embodiment, since the joining process to be carried out is merely injecting the bonding members 80 and 81 into the gaps 35 and 36 and curing the bonding members 80 and 81, the process is even more simplified than the joining process carried out for using the inclined-arm securing member 45. Moreover, since the inclined-arm securing member 45 can be omitted, the cost of the mobile telephone can be reduced through reducing the number of components, and, at the same time, the same advantages as those in the above-described embodiments can be achieved.

### [Other Variations]

The above-described embodiments and variations are applied to mobile telephones. Instead, the embodiments and variations may be applied to electronic apparatuses, such as personal handy-phone systems (PHSs), personal digital assistants (PDAs), portable game devices, digital cameras, moving-image acquisition devices, personal notebook computers, or containers in which a cover and container part is joined with a hinge. In any of the cases, the same advantages as those described above can be achieved.

Finally, the above-described embodiments and variations are examples. Therefore, the claimed invention is not limited to the above-described embodiments and variations and various modifications may be made to the design etc., so long as the modifications are within the scope of the claimed invention.

What is claimed is:

1. An electronic apparatus comprising:
a first case;
a second case having an inclined arm fitting part;
a hinge enabling the first and second cases to rotate around a first rotational axis;
a secured piece secured to the hinge and the second case, the secured piece having an inclined arm part that fits into the inclined arm fitting part; and
an inclined arm securing member configured to secure the inclined arm part fit to the inclined arm fitting part by insertion into a pair of gaps provided between the inclined arm fitting part and the inclined arm part.

2. The electronic apparatus according to claim 1, wherein the inclined arm part includes a rail protruding away from the inclined arm fitting part and provided at a predetermined oblique angle when the rail is fit to the inclined arm fitting part.

3. The electronic apparatus according to claim 2, wherein the inclined arm securing member has a pair of protrusions configured to contact substantially a center of the rail when the inclined arm securing member is inserted into the gaps.

4. The electronic apparatus according to claim 2, further comprising:
a securing pin configured to secure the inclined arm securing member to the rail; and
a pin insertion hole in the rail into which the securing pin is inserted.

5. The electronic apparatus according to claim 1, wherein the inclined arm securing member is formed of a cured adhesive that has cured over time or by being irradiated with predetermined light after being injected into and filling the gaps.

6. The electronic apparatus according to claim 1, wherein the secured piece has a second arm part that extends in a direction orthogonal to the inclined arm part, the second case has a second fitting part that extends in a direction orthogonal to the inclined arm fitting part, the inclined arm part has a first protruding screw hole part, the second arm part has a second protruding screw hole part, the inclined arm fitting part has a first depressed screw hole part, the second fitting part has a second depressed screw hole part, the first protruding screw hole part is configured to be inserted into the first depressed screw hole part, and the second protruding screw hole part is configured to be inserted into the second depressed screw hole part.

7. The electronic apparatus according to claim 7, wherein a diameter of the second depressed screw hole part is set such that the second protruding screw hole part fits into the second depressed screw hole part tightly,
a diameter of the first depressed screw hole part is set such that a predetermined gap is formed between the first protruding screw hole part and the first depressed screw hole part, and
the secured piece is configured to pivot around a rotational axis formed by the second depressed screw hole part and the second protruding screw hole part to adjust an alignment of the inclined arm part with respect to the inclined arm fitting part.

8. The electronic apparatus according to claim 1, further comprising:
a second secured piece secured to the hinge and the first case.

9. The electronic apparatus according to claim 1, wherein the hinge is configured to rotate the first and second cases around a second rotational axis substantially orthogonal with the first rotational axis.

10. A method of securing a hinge of an electronic apparatus having a first case and a second case, the hinge including a secured piece secured to the second case, the second case having an inclined arm fitting part and the secured piece having an inclined arm part, the method comprising:
securing the inclined arm part fit to the inclined arm fitting part by inserting an inclined arm securing member into a pair of gaps provided between the inclined arm fitting part and the inclined arm part.

11. The method according to claim 10, wherein the inclined arm part includes a rail protruding away from the inclined arm fitting part and provided at a predetermined oblique angle when the rail is fit to the inclined arm fitting part, and the method includes mounting the inclined arm securing member over the rail when the inclined arm securing member is inserted into the pair of gaps.

12. The method according to claim 11, wherein the inclined arm securing member has a pair of protrusions, and the method includes contacting the protrusions to substantially a center of the rail when inserting the inclined arm securing member into the gaps.

13. The method according to claim 11, further comprising:
securing the inclined arm securing member to the rail by inserting a securing pin through the inclined arm securing member and into a pin insertion hole in the rail.

14. The method according to claim 10, wherein the inclined arm securing member is made of an adhesive, and the inclined arm securing member is inserted into the gaps by injecting the adhesive into the gaps and curing the adhesive over time or irradiating the adhesive with predetermined light.

15. The method according to claim 10, wherein the secured piece has a second arm part that extends in a direction orthogonal to the inclined arm part, the second case has a second fitting part that extends in a direction orthogonal to the inclined arm fitting part, the inclined arm part has a first protruding screw hole part, the second arm part has a second protruding screw hole part, the inclined arm fitting part has a first depressed screw hole part, the second fitting part has a second depressed screw hole part, the first protruding screw hole part is configured to be inserted into the first depressed screw hole part, and the second protruding screw hole part is configured to be inserted into the second depressed screw hole part, a diameter of the second depressed screw hole part is set such that the second protruding screw hole part fits into the second depressed screw hole part tightly, a diameter of the first depressed screw hole part is set such that a predetermined gap is formed between the first protruding screw hole part and the first depressed screw hole part, and
the method includes pivoting the second secured piece around a rotational axis formed by the second depressed screw hole part the second protruding screw hole part to adjust an alignment of the inclined arm part with respect to the inclined arm fitting part.
